(19) United States
(12) Patent Application Publication
(10) Pub. No.: US 2026/0193774 A1
(43) Pub. Date: Jul. 9, 2026

(54) DEPOSITION OF YTTRIUM CARBIDE (YC) FILM

(71) Applicant: L'Air Liquide, Société Anonyme pour l'Etude et l'Exploitation des Procédés Georges Claude, Paris (FR)

(72) Inventors: Su-Hyun KIM, Seoul (KR); Soo-Hyun KIM, Gyeongsan (KR); Wontae NOH, Seoul (KR)

(21) Appl. No.: 19/009,761

(22) Filed: Jan. 3, 2025

(51) Int. Cl. C23C 16/32; C23C 16/455

(52) U.S. Cl. CPC C23C 16/32; C23C 16/45553

(57) ABSTRACT

A method for forming rare earth carbide films comprises the steps of:
a) exposing a substrate to a vapor of a rare earth-containing film-forming composition;
b) exposing the substrate to a co-reactant; and
c) repeating the steps of a) and b) until a desired thickness of the rare earth carbide films is deposited on the substrate using a vapor deposition process,
   wherein the rare earth-containing film-forming composition comprises a Cp rare earth-containing precursor having the formula:

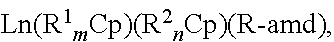

wherein R-amd is RNC(CH₃)═NR; Cp is cyclopentadienyl; Ln is selected from Sc, Y, La, Ce, Pr, Nd, Pm, Sm, Eu, Gd, Tb, Dy, Ho, Er, Tm, Yb or Lu; R¹, R² and R each are independently selected from a hydrogen atom, a C₁ to C₅ linear or branched alkyl-group, a C₃ to C₅ cyclic alkyl-group; m and n are integers. The precursor may be Y(EtCp)₂(iPr-amd).

### TECHNICAL FIELD

The present invention relates to rare earth-containing precursors and methods of using the same to deposit rare earth-containing films in semiconductor industry, in particular, to the cyclopentadienyl rare earth precursor Y(EtCp)₂(iPr-amd) and the deposited film YCₓ, wherein x is between 0.3 and 4, preferably between 0.5 and 2.

### BACKGROUND

Transition metal carbide and nitrides are widely used materials in industrial applications due to their exceptional hardness, high melting temperatures, and chemical stability. In particular, transition metal carbides are stable at high temperatures with a higher phase transition temperature than other nitrides and oxides. Additionally, they possess excellent resistances to the oxidation and corrosion, making them valuable in various technological applications, including diffusion barrier, metal gate, glue layer for W-plug, cap. Electrode, even for extreme ultraviolet radiation (EUV) pellicle.

Various studies have been conducted on transition metal carbides such as YCₓ, MoC, NbC, using atomic layer deposition (ALD) process with metal organic precursors.

U.S. Pat. No. 9,129,620B2 discloses a device comprises a near field transducer (NFT), the NFT having a disc and a peg, and the peg having an air bearing surface thereof and at least one adhesion layer positioned on at least the air bearing surface of the peg, the adhesion layer comprising one or more of the following groups: a. tungsten (W), molybdenum (Mo), chromium (Cr), silicon (Si), nickel (Ni), tantalum (Ta), titanium (Ti), yttrium (Y), vanadium (V), magnesium (Mg), cobalt (Co), tin (Sn), niobium (Nb), hafnium (Hf), and combinations thereof; b. tantalum oxide, titanium oxide, tin oxide, indium oxide, and combinations thereof; c. vanadium carbide (VC), tungsten carbide (WC), titanium carbide (TIC), chromium carbide (CrC), cobalt carbide (CoC), nickel carbide (NiC), yttrium carbide (YC), molybdenum carbide (MoC), and combinations thereof; and d. titanium nitride (TIN), zirconium nitride (ZrN), hafnium nitride (HIN), and combinations thereof. The process for forming the adhesion layers include ALD.

U.S. Pat. No. 7,611,751B2 to Kai-Erik Elers discloses metal carbide films formed in an atomic layer deposition (ALD) process comprise one or more metals selected from the group consisting of titanium (Ti), zirconium (Zr), hafnium (Hf), vanadium (V), niobium (Nb), tantalum (Ta), chromium (Cr), molybdenum (Mo), tungsten (W), manganese (Mn), rhenium (Re), iron (Fe), cobalt (Co), nickel (Ni), copper (Cu), silver (Ag), gold (Au), palladium (Pd), platinum (Pt), rhodium (Rh), iridium (Ir), ruthenium (Ru), osmium (Os) and aluminum (Al).

U.S. Pat. No. 9,631,272B2 discloses atomic layer deposition of metal carbide films using aluminum hydrocarbon compounds in which the metal carbide film may be stoichiometric, e.g., TaC, or non-stoichiometric, e.g., TaCₓ, where ‘x’ is greater than one if the film has excess carbon or less than one if the film is carbon deficient.

U.S. Pat. No. 11,761,081B2 discloses methods for depositing tungsten or molybdenum films with CVD and ALD, such as molybdenum carbide (Mo₂C) or tungsten carbide (WC).

However, researches regarding both the processes of yttrium carbide (YC) thin film, one of the transition metal carbides, and their properties are still in the very early stages and pioneering studies exploring the deposition possibility of YC thin film and its potential applications based on the characteristics of the deposited YC thin film are necessary. Therefore, pioneering research is needed to explore the deposition feasibility, properties, and potential applications of YC thin films.

### SUMMARY

Disclosed is a method for forming rare earth carbide films, the method comprising the steps of:
a) exposing a substrate to a vapor of a rare earth-containing film-forming composition;
b) exposing the substrate to a co-reactant; and
c) repeating the steps of a) and b) until a desired thickness of the rare earth carbide films is deposited on the substrate using a vapor deposition process,
   wherein the rare earth-containing film-forming composition comprises a cyclopentadienyl rare earth-containing precursor having the formula:

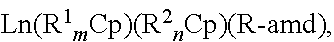

wherein R-amd is an amidinate ligand, RNC(CH₃)═NR, wherein the two R groups are the same or different; Cp is cyclopentadienyl; Ln is selected from Sc, Y, La, Ce, Pr, Nd, Pm, Sm, Eu, Gd, Tb, Dy, Ho, Er, Tm, Yb or Lu; R¹, R², and R each are independently selected from a hydrogen atom, a C₁ to C₅ linear or branched alkyl-group, a C₃ to C₅ cyclic alkyl-group; and m and n are integers. The disclosed deposition method may include one or more of the following features:
R being defined an alkyl group;
R being selected from Me, Et, nPr, iPr, nBu, iBi, sBu or tBu;
Ln is Sc, Y, La, Ce, Pr, Nd, Pm, Sm, Eu, Gd, Tb, Dy, Ho, Er, Tm, Yb or Lu;
Ln is Y;
the co-reactant being an H source;
the co-reactant being H₂ or plasma H₂;
the vapor deposition process being a plasma enhanced ALD process;
a ratio of rare earth to carbon in the rare earth carbide film being between 0.3 and 4;
a ratio of rare earth to carbon in the rare earth carbide film being between 0.5 and 2;
the rare earth carbide film being YCₓ, wherein x is between 0.3 and 4;
the rare earth carbide film being YCₓ, wherein x is between 0.5 and 2;
the cyclopentadienyl rare earth-containing precursor being Y(EtCp)₂(iPr-amd), wherein “iPr-amd” represents iPrNC(CH₃)═NiPr;
the substrate being SiO;
a deposition temperature being held between about 100° C. and about 800° C.; and
a deposition temperature being held between about 150° C. and about 500° C.

Disclosed is a method for forming rare earth carbide films, the method comprising the steps of:
d) exposing a substrate to a vapor of Y(EtCp)₂(iPr-amd);
e) exposing the substrate to a co-reactant; and
   repeating the steps of a) and b) until a desired thickness of the rare earth carbide films is deposited on the substrate using a vapor deposition process. The disclosed deposition method may include one or more of the following features:
iPr-amd being iPrNC(CH₃)═NiPr ligand;
the co-reactant being an H source;
the co-reactant being H₂ or plasma H₂;
a range of deposition temperature being from approximately 150 to approximately 350° C.;
the vapor deposition process being an atomic layer deposition (ALD) process; and
the vapor deposition process being a plasma enhanced ALD process.

Disclosed is a method for forming YCₓ films, wherein x is between 0.3 and 4, the method comprising the steps of:
a) exposing a SiO substrate to a vapor of Y(EtCp)₂(iPr-amd);
b) exposing the SiO substrate to a co-reactant H₂ plasma; and
   repeating the steps of a) and b) until a desired thickness of the YCₓ films is deposited on the SiO substrate using ALD process. The disclosed deposition method may include one or more of the following features:
iPr-amd being iPrNC(CH₃)═NiPr ligand;
x being between 0.5 and 2; and
a range of deposition temperature being from approximately 150° C. to approximately 350° C.

### Notation and Nomenclature

The following detailed description and claims utilize a number of abbreviations, symbols, and terms, which are generally well known in the art.

As used herein, the indefinite article “a” or “an” means one or more.

As used herein, “about” or “around” or “approximately” in the text or in a claim means±10% of the value stated.

As used herein, “room temperature” in the text or in a claim means from approximately 20° C. to approximately 30° C.

The term “substrate” refers to a material or materials on which a process is conducted. The substrate may refer to a wafer having a material or materials on which a process is conducted. The substrates may be any suitable wafer used in semiconductor, photovoltaic, flat panel, or LCD-TFT device manufacturing. The substrate may also have one or more layers of differing materials already deposited upon it from a previous manufacturing step. For example, the wafers may include silicon layers (e.g., crystalline, amorphous, porous, etc.), silicon containing layers (e.g., SiO₂, SiN, SiON, SiCOH, etc.), metal containing layers (e.g., copper, cobalt, ruthenium, tungsten, platinum, palladium, nickel, ruthenium, gold, etc.) or combinations thereof. Furthermore, the substrate may be planar or patterned. The substrate may be an organic patterned photoresist film. The substrate may include layers of oxides which are used as dielectric materials in MEMS, 3D NAND, MIM, DRAM, or FeRam device applications (for example, ZrO₂ based materials, HfO₂ based materials, TiO₂ based materials, Al₂O₃ based materials, rare earth oxide based materials, ternary oxide based materials, etc.) or nitride-based films (for example, TaN, TIN, NbN) that are used as electrodes. One of ordinary skill in the art will recognize that the terms “film” or “layer” used herein refer to a thickness of some material laid on or spread over a surface and that the surface may be a trench or a line. Throughout the specification and claims, the wafer and any associated layers thereon are referred to as substrates.

The term “wafer” or “patterned wafer” refers to a wafer having a stack of films on a substrate and at least the top-most film having topographic features that have been created in steps prior to the deposition of the Group V (five)-containing film.

The term “aspect ratio” refers to a ratio of the height of a trench (or aperture) to the width of the trench (or the diameter of the aperture).

The term “high aspect ratio” refers to an aspect ratio larger than approximately 2:1, preferably an aspect ratio ranging from approximately 2:1 to approximately 200:1.

Note that herein, the terms “film” and “layer” may be used interchangeably. It is understood that a film may correspond to, or related to a layer, and that the layer may refer to the film. Furthermore, one of ordinary skill in the art will recognize that the terms “film” or “layer” used herein refer to a thickness of some material laid on or spread over a surface and that the surface may range from as large as the entire wafer to as small as a trench or a line.

As used herein, the abbreviation “NAND” refers to a “Negative AND” or “Not AND” (electronic logic gate); the abbreviation “2D” refers to 2 dimensional gate structures on a planar substrate; the abbreviation “3D” refers to 3 dimensional or vertical gate structures, wherein the gate structures are stacked in the vertical direction.

Note that herein, the terms “deposition temperature” and “substrate temperature” may be used interchangeably. It is understood that a substrate temperature may correspond to, or be related to a deposition temperature, and that the deposition temperature may refer to the substrate temperature.

The term “film-forming composition” refers to a composition used for deposition of a film. The film-forming composition may include, but is not limited to, a precursor, a solvent and/or a carrier gas. Furthermore, the film-forming composition may include, but is not limited to, a precursor, optionally a solvent, optionally a carrier gas, and optionally one or more co-reactant(s). Herein, the precursor may be supplied either in a neat form or in a blend with a suitable solvent. The precursor may be present in varying concentrations in the solvent. Alternatively, the precursor may be vaporized by passing a carrier gas into a container that contains the precursor or by bubbling the carrier gas into the precursor. The carrier gas and precursor are then introduced into a reactor as a vapor. The co-reactant may be an oxidizer, a reducing agent, a dilute gas, an additive, an inhibitor, an additional or a secondary precursor, etc., for assisting in formation of the film. Here an inert gas selected from N₂, He, Ar, Kr, Xe may be used as the carrier gas and/or the dilute gas.

Note that herein, the terms “precursor” and “deposition compound” and “deposition gas” may be used interchangeably when the precursor is in a gaseous state at room temperature and ambient pressure. It is understood that a precursor may correspond to, or be related to a deposition compound or deposition gas, and that the deposition compound or deposition gas may refer to the precursor.

Certain abbreviations, symbols, and terms are used throughout the following description and claims also include: the abbreviation “Ln” refers to the lanthanide group, which includes the following elements: scandium (“Sc”), yttrium (“Y”), lutetium (“Lu”), lanthanum (“La”), cerium (“Ce”), praseodymium (“Pr”), neodymium (“Nd”), promethium (“Pm”), samarium (“Sm”), europium (“Eu”), gadolinium (“Gd”), terbium (“Tb”), dysprosium (“Dy”), holmium (“Ho”), erbium (“Er”), thulium (“Tm”), ytterbium (“Yb”) or lutetium (“Lu”); the abbreviation “Cp” refers to cyclopentadiene; the abbreviation “Å” refers to angstroms; prime (“ ”) is used to indicate a different component than the first, for example (LnLn′)O₃ refers to a lanthanide oxide containing two different lanthanide elements; the term “aliphatic group” refers to a C₁-C₅ linear or branched chain alkyl group; It should be understood that elements may be referred to by these abbreviation (e.g., Si refers to silicon, N refers to nitrogen, O refers to oxygen, C refers to carbon, H refers to hydrogen, F refers to fluorine, etc.).

As used herein, the abbreviation “R-amd” refers to the amidinate ligand RNC(CH₃)═NR, wherein R is defined a hydrogen, an alkyl group, i.e., a C₁ to C₅ linear or branched alkyl-group, a C₃ to C₅ cyclic alkyl-group, such as Me, Et, nPr, iPr, nBu, iBi, sBu or tBu, and the two R groups can be the same or different. For example, “iPr-amd” represents iPrNC(CH₃)═NiPr ligand. Although depicted here as having a double bond between the C and N of the ligand backbone, one of ordinary skill in the art will recognize that the amidinate, forming idinate and guanidinate ligands, does not contain a fixed double bond. Instead, one electron is delocalized amongst the N—C—N chain.

As used herein, the term “hydrocarbon” refers to a saturated or unsaturated function group containing exclusively carbon and hydrogen atoms. As used herein, the term “alkyl group” refers to saturated functional groups containing exclusively carbon and hydrogen atoms. An alkyl group is one type of hydrocarbon. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation “Me” refers to a methyl group; the abbreviation “Et” refers to an ethyl group; the abbreviation “Pr” refers to a propyl group; the abbreviation “nPr” refers to a “normal” or linear propyl group; the abbreviation “iPr” refers to an isopropyl group; the abbreviation “Bu” refers to a butyl group; the abbreviation “nBu” refers to a “normal” or linear butyl group; the abbreviation “tBu” refers to a tert-butyl group, also known as 1,1-dimethylethyl; the abbreviation “sBu” refers to a sec-butyl group, also known as 1-methylpropyl; the abbreviation “iBu” refers to an iso-butyl group, also known as 2-methylpropyl; the abbreviation “amyl” refers to an amyl or pentyl group; the abbreviation “tAmyl” refers to a tert-amyl group, also known as 1,1-dimethylpropyl.

Please note that the rare earth-containing (e.g., Y) films or layers deposited, such as yttrium carbide, may be listed throughout the specification and claims without reference to their proper stoichiometry (e.g., YCₓ, wherein x is between 0.3 and 4, preferably between 0.5 and 2). These layers may also contain Hydrogen, typically from 0 atomic % to 15 atomic %. However, since not routinely measured, any film compositions given ignore their H content, unless explicitly stated otherwise. Furthermore, the concentration of hydrogen may be further tuned by performing post deposition annealing to obtain desired thin film properties.

Ranges may be expressed herein as from about one particular value, and/or to about another particular value. When such a range is expressed, it is to be understood that another embodiment is from the one particular value and/or to the other particular value, along with all combinations within said range. Any and all ranges recited herein are inclusive of their endpoints (i.e., x=1 to 4 or x ranges from 1 to 4 includes x=1, x=4, and x=any number in between), irrespective of whether the term “inclusively” is used.

Reference herein to “one embodiment” or “an embodiment” means that a particular feature, structure, or characteristic described in connection with the embodiment may be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula MR¹ₓ(NR²R³)₍₄₋ₓ₎, where x is 2 or 3, the two or three R¹ groups may, but need not be identical to each other or to R² or to R³. Further, it should be understood that unless specifically stated otherwise, values of R groups are independent of each other when used in different formulas.

As used in this application, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion.

Additionally, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

“Comprising” in a claim is an open transitional term which means the subsequently identified claim elements are a nonexclusive listing (i.e., anything else may be additionally included and remain within the scope of “comprising”). “Comprising” is defined herein as necessarily encompassing the more limited transitional terms “consisting essentially of” and “consisting of”; “comprising” may therefore be replaced by “consisting essentially of” or “consisting of” and remain within the expressly defined scope of “comprising”.

“Providing” in a claim is defined to mean furnishing, supplying, making available, or preparing something. The step may be performed by any actors in the absence of express language in the claim to the contrary.

### BRIEF DESCRIPTION OF THE DRAWINGS

For a further understanding of the nature and objects of the present invention, reference should be made to the following detailed description, taken in conjunction with the accompanying drawings, in which like elements are given the same or analogous reference numbers and wherein:

FIG. 1 is an ALD window of Y(EtCp)₂(iPr-amd) and resistivity as the temperature;

FIG. 2 is an X-ray diffraction (XRD) peaks of Y₂C according to the temperature;

FIG. 3 is a Linear growth rate with H₂ plasma as a reactant at 250° C.; and

FIG. 4 is X-ray Reflectometry (XRR) from the film of 100 cycle's process at 250° C.

### DESCRIPTION OF PREFERRED EMBODIMENTS

Disclosed are rare earth-containing film-forming compositions comprising rare earth-containing precursors and methods of depositing rare earth carbide films using the rare earth-containing film-forming compositions via chemical vapor deposition (CVD) processes, such as atomic layer deposition (ALD) process, with particular emphases on diffusion barriers as well as potential applications in various technology areas. Specifically, the disclosed is a method for depositing Yittrium carbide (YCₓ, wherein x is between 0.3 and 4, preferably between 0.5 and 2) film using Y-containing precursors through ALD process. A deposition method for Yttrium carbide with Y(EtCp)₂(iPr-amd) and H₂ plasma onto SiO₂ substrate is disclosed.

The disclosed rare earth-containing precursors may be a cyclopentadienyl rare earth compound, having the formula:

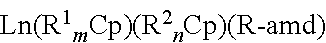

wherein R-amd is an amidinate ligand, RNC(CH₃)═NR, wherein the two R groups can be the same or different; Cp is cyclopentadienyl; Ln is selected from Sc, Y, La, Ce, Pr, Nd, Pm, Sm, Eu, Gd, Tb, Dy, Ho, Er, Tm, Yb or Lu; R¹, R² and R each are independently selected from a hydrogen atom, a C₁ to C₅ linear or branched alkyl-group, a C₃ to C₅ cyclic alkyl-group; and m and n are integers. Preferably, R is Me, Et, nPr, iPr, nBu, iBi, sBu or tBu.

In some embodiments, the rare earth-containing precursors may be Sc and Y precursor or lanthanide elements precursors selected from La to Lu (La, Ce, Pr, Nd, Pm, Sm, Eu, Gd, Tb, Dy, Ho, Er, Tm, Yb or Lu) precursors.

In some embodiments, the rare earth-containing precursors may be Sc, Y, La, Ce, Nd, Pr, Yb, Lu precursors.

In some embodiments, the rare earth-containing precursors may be Sc or Y.

In some embodiments, the rare earth-containing precursors may be Y.

Exemplary rare earth-containing precursors include Y(EtCp)₂(iPr-amd). Here “iPr-amd” represents a iPrNC(CH₃)═NiPr ligand.

The disclosed rare earth-containing film formed by deposition of the rare earth-containing film-forming composition containing a rare earth precursor may be a rare earth carbide in which rare earth to carbon ratio preferably ranging between 0.3 and 4, preferably between 0.5 and 2.

Using the disclosed rare earth-containing precursors may obtain unexpected ALD results. For example, in Y(EtCp)₂(iPr-amd) structure, iPr-amd ligand (iPrNC(CH₃)═NiPr) will be a leaving group upon absorption onto a surface, leaving Y(EtCp)₂ on the surface, which lead to ALD of YCₓ film. Furthermore, Ln elements are used extensively in hard coatings, especially Y is a good candidate as a form of YOₓ (wherein x is between 0.3 and 4, preferably between 0.5 and 2) for protection layers. The disclosed rare earth-containing precursors have high volatility which may affect the deposition process efficiency.

Purity of the disclosed rare earth-containing film-forming composition including the disclosed rare earth precursors is greater than 95% w/w (i.e., 95.0% w/w to 100.0% w/w), preferably greater than 98% w/w (i.e., 98.0% w/w to 100.0% w/w), and more preferably greater than 99% w/w (i.e., 99.0% w/w to 100.0% w/w). One of ordinary skill in the art will recognize that the purity may be determined by H NMR and gas liquid chromatography with mass spectrometry. The disclosed rare earth-containing film-forming composition may contain any of the following impurities: pyrazoles; pyridines; alkylamines; alkylamines; THF; ether; pentane; cyclohexane; heptanes; benzene; toluene; chlorinated metal compounds; lithium, sodium, potassium pyrazolyl. The total quantity of these impurities is preferably below 5% w/w (i.e., 0.0% w/w to 5.0% w/w), preferably below 2% w/w (i.e., 0.0% w/w to 2.0% w/w), and more preferably below 1% w/w (i.e., 0.0% w/w to 1.0% w/w). The composition may be purified by recrystallisation, sublimation, distillation, and/or passing the gas liquid through a suitable adsorbent, such as a 4 Å molecular sieve.

Purification of the disclosed rare earth-containing film-forming composition may also result in metal impurities at the 0 ppbw to 1 ppmw, preferably 0-500 ppbw (part per billion weight) level. These metal impurities may include, but are not limited to, Aluminum (AI), Arsenic (As), Barium (Ba), Beryllium (Be), Bismuth (Bi), Cadmium (Cd), Calcium (Ca), Chromium (Cr), Cobalt (Co), Copper (Cu), Gallium (Ga), Germanium (Ge), Hafnium (Hf), Zirconium (Zr), Indium (In), Iron (Fe), Lead (Pb), Lithium (Li), Magnesium (Mg), Manganese (Mn), Tungsten (W), Nickel (Ni), Potassium (K), Sodium (Na), Strontium (Sr), Thorium (Th), Tin (Sn), Titanium (Ti), Uranium (U), and Zinc (Zn).

Also disclosed are methods for forming rare earth-containing layers on a substrate using a vapor deposition process. Applicants believe, and demonstrate in the Example that follows, that the disclosed rare earth-containing film-forming compositions are suitable for atomic layer deposition (ALD). More particularly, the disclosed rare earth-containing film-forming compositions are capable of surface saturation, self limited growth per cycle, and perfect step coverage on aspect ratios ranging from approximately 2:1 to approximately 200:1, and preferably from approximately 20:1 to approximately 100:1. Additionally, the disclosed rare earth-containing film-forming compositions have high decomposition temperatures, indicating good thermal stability to enable ALD. The high decomposition temperatures permit ALD at higher temperatures, resulting in films having higher purity.

The disclosed method may be useful in the manufacture of semiconductor, photovoltaic, LCD-TFT, flat panel type devices. The disclosed rare earth-containing film-forming compositions may be used to deposit rare earth-containing films using any deposition methods known to those of skill in the art. Examples of suitable deposition methods include chemical vapor deposition (CVD). Exemplary CVD methods include thermal CVD, plasma enhanced CVD (PECVD), pulsed CVD (PCVD), low pressure CVD (LPCVD), sub-atmospheric CVD (SACVD) atmospheric pressure CVD (APCVD), hot-wire CVD (HWCVD, also known as cat-CVD, in which a hot wire serves as an energy-source for the deposition process), radicals incorporated CVD, ALD, thermal ALD, plasma enhanced ALD (PEALD), spatial ALD, hot-wire ALD (HWALD), radicals incorporated ALD, and combinations thereof, Super critical fluid deposition may also be used. The deposition method is preferably ALD, PE-ALD, spatial ALD in order to provide suitable step coverage and film thickness control,

The disclosed rare earth-containing film-forming compositions may be supplied either in neat form in a blend with a suitable solvent, such as ethyl benzene, xylene, mesitylene, decalin, decane, dodecane. The disclosed rare earth-containing precursors may be present in varying concentrations in the solvent.

The neat or blended disclosed rare earth-containing film-forming compositions are introduced into a reactor in vapor form by conventional means, such as tubing and/or flow meters. The vapor form may be produced by vaporizing the neat or blended composition through a conventional vaporization step such as direct vaporization, distillation, by bubbling, or by using a sublimator. The neat or blended composition may be fed in liquid state to a vaporizer where it is vaporized before it is introduced into the reactor. Alternatively, the neat or blended composition may be vaporized by passing a carrier gas into a container containing the composition by bubbling the carrier gas into the composition. The carrier gas may include, but is not limited to, Ar, He, N₂, and mixtures thereof. Bubbling with a carrier gas may also remove any dissolved oxygen present in the neat blended composition. The carrier gas and composition are then introduced into the reactor as a vapor,

If necessary, the container containing the disclosed rare earth-containing film-forming compositions may be heated to a temperature that permits the composition to be in its liquid phase and to have a sufficient vapor pressure. The container may be maintained at temperatures in the range of, for example, approximately 0° C. to approximately 200° C. Those skilled in the art recognize that the temperature of the container may be adjusted in a known manner to control the amount of precursor vaporized.

The reactor may be any enclosure chamber within a device in which deposition methods take place such as without limitation, a parallel-plate type reactor, a cold-wall type reactor, a hot-wall type reactor, a single-wafer reactor, a multi-wafer reactor, a powder ALD reactor, other types of deposition systems under conditions suitable to cause the compounds to react and form the deposition films. One of ordinary skill in the art will recognize that any of these reactors may be used for either ALD or CVD deposition processes.

The reactor contains one or more substrates onto which the films will be deposited. A substrate is generally defined as a material on which a process is conducted. The substrates may be any suitable substrate used in semiconductor, photovoltaic, fiat panel, LCD-TFT device manufacturing. Examples of suitable substrates include wafers, such as silicon, silica, glass, GaAs wafers. The wafer may have one or more layers of differing materials deposited on it from a previous manufacturing step. For example, the wafers may include a dielectric layer. Furthermore, the wafers may include silicon layers (crystalline, amorphous, porous, etc.), silicon oxide layers, silicon nitride layers, silicon oxy nitride layers, carbon doped silicon oxide (SiCOH) layers, metal, metal oxide, metal nitride layers (Ti, Ru, Ta, etc.) and combinations thereof. Additionally, the wafers may include copper layers noble metal layers (e.g., platinum, palladium, rhodium, and gold). The layers may be planar or patterned. The disclosed processes may deposit the rare earth-containing layer directly on the wafer or directly on one or more layers on top of the wafer (when patterned layers form the substrate). Furthermore, one of ordinary skill in the art will recognize that the terms “film” and “layer” used herein refer to a thickness of some material laid on spread over a surface and that the surface may be a hole, a trench or a line. Throughout the specification and claims, the wafer and any associated layers thereon are referred to as substrates.

The substrate may also be a powder, such as the powder used in rechargeable battery technology. A non-limiting number of powder materials include LNMC (Lithium Nickel Manganese Cobalt Oxide), LCO (Lithium Cobalt Oxide), LFP (Lithium Iron Phosphate), and other battery cathode materials.

The temperature and the pressure within the reactor are held at conditions suitable for ALD. In other words, after introduction of the vaporized disclosed composition into the chamber, conditions within the chamber are such that at least part of the precursor is deposited onto the substrate to form a rare earth-containing layer. For instance, the pressure in the reactor or the deposition pressure may be held between about 10-3 torr and about 100 Torr, more preferably between about 10-2 and 100 Torr, as required per the deposition parameters. Likewise, the temperature in the reactor or the deposition temperature may be held between about 100° C. and about 800° C., preferably between about 150° C. and about 500° C. One of ordinary skill in the art will recognize that-“at least part of the precursor is deposited” means that some all of the precursor reacts with adheres to the substrate.

The temperature of the reactor may be controlled by either controlling the temperature of the substrate holder controlling the temperature of the reactor wall. Devices used to heat the substrate are known in the art. The reactor wall is heated to a sufficient temperature to obtain the desired film at a sufficient growth rate and with desired physical state and composition. A non-limiting exemplary temperature range to which the reactor wall may be heated includes from approximately 50° C. to approximately 800° C. When a plasma deposition process is utilized, the deposition temperature may range from approximately 50° C. to approximately 500° C., preferably, from approximately 100° C. to approximately 500° C., more preferably, from approximately 150° C. to approximately 500° C. Alternatively, when a thermal process is performed, the deposition temperature may range from approximately 100° C. to approximately 800° C.

In addition to the disclosed rare earth-containing precursor, a co-reactant may be introduced into the reactor. When a target is a conductive film, the co-reactant may be H₂, H₂CO, N₂H₄, NH₃, a primary amine, a secondary amine, a tertiary amine, trisilylamine, a hydrazine N(SiH₃)₃, B₂H₆, Si₂H₆, radicals thereof, and mixtures thereof. Preferably, the co-reactant is H₂ or NH₃. In some embodiments, the co-reactant may be an H source that is H₂ gas, plasma H₂. Alternatively, when a target is a dielectric film, the co-reactant may be an oxidizing gas such as one of O₂, O₃, H₂O, H₂O₂, NO, N₂O, NO₂, oxygen containing radicals such as O—OH—, carboxylic acids, formic acid, acetic acid, propionic acid, and mixtures thereof. Preferably, the oxidizing gas is selected from the group consisting of O₃, H₂O₂ and H₂O.

The co-reactant may be treated by a plasma, in order to decompose the reactant into its radical form, N₂ may also be utilized as a nitrogen source gas when treated with plasma. For instance, the plasma may be generated with a power ranging from about 10 W to about 1000 W, preferably from about 50 W to about 500 W. The plasma may be generated present within the reactor itself. Alternatively, the plasma may generally be at a location removed from the reactor, for instance, in a remotely located plasma system. One of skill in the art will recognize methods and apparatus suitable for such plasma treatment.

For example, the co-reactant may be introduced into a direct plasma reactor, which generates plasma in the reaction chamber, to produce the plasma-treated reactant in the reaction chamber. The co-reactant may be introduced and held in the reaction chamber prior to plasma processing. Alternatively, the plasma processing may occur simultaneously with the introduction of the reactant. In-situ plasma is typically a 13.56 MHz RF inductively coupled plasma that is generated between the showerhead and the substrate holder. The substrate and the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the co-reactant using in-situ plasma is typically less than achieved using a remote plasma source for the same power input and is therefore not as efficient in reactant dissociation as a remote plasma system, which may be beneficial for the deposition of rare earth-containing films on substrates easily damaged by plasma.

Alternatively, the plasma-treated co-reactant may be produced outside of the reaction chamber, for example, a remote plasma to treat the co-reactant prior to passage into the reaction chamber.

The ALD conditions within the chamber allow the disclosed rare earth-containing film-forming composition adsorbed chemisorbed on the substrate surface to react and form a rare earth-containing film on the substrate. In some embodiments, it is believed that plasma-treating the co-reactant may provide the co-reactant with the energy needed to react with the disclosed rare earth-containing film-forming composition.

Depending on what type of film is desired to be deposited, an additional precursor compound may be introduced into the reactor. The additional precursor may be used to provide additional elements to the rare earth-containing film. The additional elements may include Group I elements (lithium, Sodium, potassium), lanthanides (Ytterbium, Erbium, Dysprosium, Gadolinium, Praseodymium, Cerium, Lanthanum, Yttrium), Group IV elements (zirconium, titanium, hafnium), main group elements (germanium, silicon, aluminium), additional different Group V elements, and mixtures thereof. When an additional precursor compound and the rare earth-containing precursor is utilized, the resultant film deposited on the substrate contains rare earth-containing compositions in combination with an additional element from the additional precursor. When the additional precursor and the rare earth-containing precursors are used in more than one ALD super cycle sequences, a nanolaminate film is obtained.

The disclosed rare earth-containing film-forming compositions and co-reactants may be introduced into the reactor sequentially (i.e., ALD). The reactor may be purged with an inert gas (e.g., N₂, He, Ar, Kr, or Xe) between the introduction of each of the disclosed rare earth-containing film-forming compositions, any additional precursors, and the co-reactants. Another example is to introduce the co-reactant continuously and to introduce the rare earth-containing film-forming composition by pulse, while activating the co-reactant sequentially with a plasma, provided that the rare earth-containing film-forming composition and the non-activated co-reactant do not substantially react at the chamber temperature and pressure conditions (CW PEALD).

Furthermore, a dilution gas may be added to the process, and is selected from Ar, He, N₂, H₂ or combinations thereof.

Each pulse of the disclosed rare earth-containing film-forming compositions may last for a time period ranging from about 0.01 seconds to about 120 seconds, alternatively from about 1 seconds to about 80 seconds, alternatively from about 5 seconds to about 30 seconds. The co-reactant may also be pulsed into the reactor, In such embodiments, the pulse of each may last for a time period ranging from about 0.01 seconds to about 120 seconds, alternatively from about 1 seconds to about 30 seconds, alternatively from about 2 seconds to about 20 seconds. In another alternative, the vaporized disclosed rare earth-containing film-forming compositions and co-reactants may be simultaneously sprayed from different sectors of a shower head (without mixing of the composition and the reactant) under which a susceptor holding several wafers is spun (spatial ALD).

Depending on particular process parameters, deposition may take place for a varying length of time. Generally, deposition may be allowed to continue as long as desired necessary to produce a film with the necessary properties. Typical film thicknesses may vary from several angstroms to several hundreds of microns, and typically from 2 to 100 nm, depending on the specific deposition process. The deposition process may also be performed as many times as necessary to obtain the desired film.

In one non-limiting exemplary ALD process, the vapor phase of the disclosed rare earth-containing film-forming compositions is introduced into the reactor, where it is contacted with a suitable substrate. Excess composition may then be removed from the reactor by purging and/or evacuating the reactor. A co-reactant (for example, O₃) is introduced into the reactor where it reacts with the absorbed rare earth-containing film-forming composition in a self-limiting manner. Any excess co-reactant is removed from the reactor by purging and/or evacuating the reactor. If the desired film is a metal oxide, this two-step process may provide the desired film thickness may be repeated until a film having the necessary thickness has been obtained.

When the co-reactant in this exemplary ALD process is treated with a plasma, the exemplary ALD process becomes an exemplary PEALD process. The co-reactant may be treated with plasma prior subsequent to introduction into the chamber.

Upon obtaining a desired film thickness, the film may be subject to further processing, such as thermal annealing, furnace-annealing, rapid thermal annealing, UV e-beam curing, and microwave annealing and/or plasma gas exposure. Those skilled in the art recognize the systems and methods utilized to perform these additional processing steps. For example, the YCₓ film may be exposed to a temperature ranging from approximately 200° C. and approximately 1000° C. for a time ranging from approximately 0.1 second to approximately 7200 seconds under an inert atmosphere, an O-containing atmosphere, H-containing atmosphere combinations thereof. Most preferably, the temperature is 400° C. for 3600 seconds under an inert atmosphere or an O-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, has been found effective to reduce oxygen-containing and nitrogen-containing contaminations (e.g., yttrium oxides and yttrium nitrides) have been reduced) of YCₓ film. This in turn tends to improve the resistivity of the film.

After annealing, the rare earth-containing films deposited by any of the disclosed processes may have a bulk resistivity at room temperature of approximately 50 μohm·cm to approximately 1,000 μohm·cm. Room temperature is approximately 20° C. to approximately 28° C. depending on the season. Bulk resistivity is also known as volume resistivity. One of ordinary skill in the art will recognize that the bulk resistivity is measured at room temperature on the rare earth-containing films that are typically approximately 50 nm thick. The bulk resistivity typically increases for thinner films due to changes in the electron transport mechanism. The bulk resistivity also increases at higher temperatures.

In another alternative, the disclosed compositions may be used as doping implantation agents. Part of the disclosed rare earth-containing film-forming composition may be deposited on top of the film to be doped.

### EXAMPLES

The following non-limiting examples are provided to further illustrate embodiments of the invention. However, the examples are not intended to be all inclusive and are not intended to limit the scope of the inventions described herein.

### Example 1

YCₓ (x is between 0.3 and 4, preferably between 0.5 and 2) thin films were deposited in a shower head type ALD reactor (IOV dX1 PEALD reactor, ISAC Research, Korea) with a sequential supply of a new Y metal organic precursor, Y(EtCp)₂(iPr-amd), as a precursor and H₂ plasma as a co-reactant. A radio-frequency power of 200 W was applied to the shower head to ignite the plasma. The range of deposition temperature was 150 to 350° C. A standard cycle of the YCₓ ALD process consisted of precursor pulsing for 10 s, co-reactant pulsing for 10 s, and purging for 10 s. This process was established according to a self-limiting growth criteria discussed below. The precursor was heated at 120° C. to obtain a suitable vapor pressure during film deposition. All the films were grown on p-type Si, SiO₂ (100 nm on Si) and TiN substrates. The thickness of the YCₓ films was measured by scanning electron microscopy (SEM, SU8220 Cold RE-SEM, Hitachi). The film resistivity was measured by combining the sheet resistance of the film measured using a four-point probe (CMT-100, AIT) with its thickness. The phase and crystallinity of the films were measured by grazing incidence X-ray diffraction (GIXRD, D8 DISCOVERY, Brucker) with Cu-Kα radiation at 1.5 KW and an incident angle θ of 3°. The density and roughness of YCₓ films were measured by X-ray Reflectometry (XRR, D8 DISCOVERY, Brucker) with Cu-Kα radiation at 1.5 KW. Cross-sectional transmission electron microscopy (TEM, HF-3300, Hitachi) was used to evaluate the step coverage of the YCₓ film on a Si trench structure. The chemical composition of the ALD YCₓ was analyzed by energy dispersive X-ray spectroscopy (EDS) and selected-area electron diffraction was performed for phase identification using the same TEM equipment.

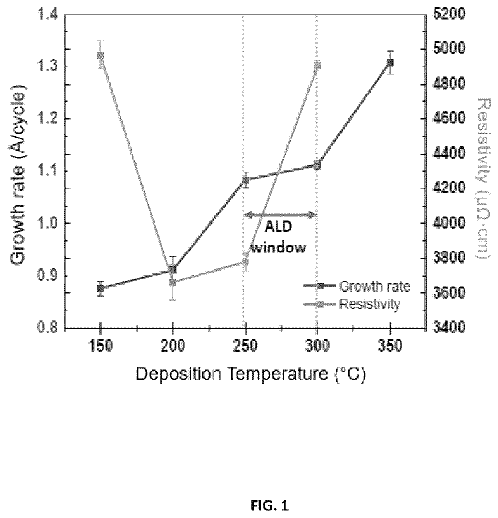

First, the study investigated the effect of substrate temperature on the ALD of YCₓ films within a temperature range of 150° C. to 350° C. At 150 to 200° C., the growth rate was ~0.09 nm/cycle, increasing to 0.11 nm/cycle at 250° C. Maintaining the same growth rate (0.11 nm/cycle) at 300° C. suggested an ALD temperature window of 250° C. to 300° C. However, at 350° C., partial precursor decomposition led to a growth rate increase to 0.13 nm/cycle in the ALD window, the lowest resistivity was observed at 250° C., increasing significantly at 300° C. as shown in FIG. 1.

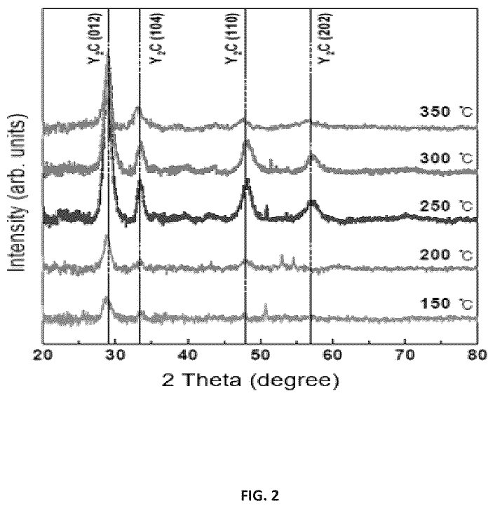

The GIXRD analysis revealed rombohedral Y₂C peaks, intensifying with higher deposition temperatures, indicating enhanced crystallinity and grain size. Conversely, at 350° C., precursor decomposition led to decreased peak intensities. Thus, 250° C. was determined as the optimal deposition temperature due to its highest crystallinity and lowest resistivity within the ALD window as shown in FIG. 2.

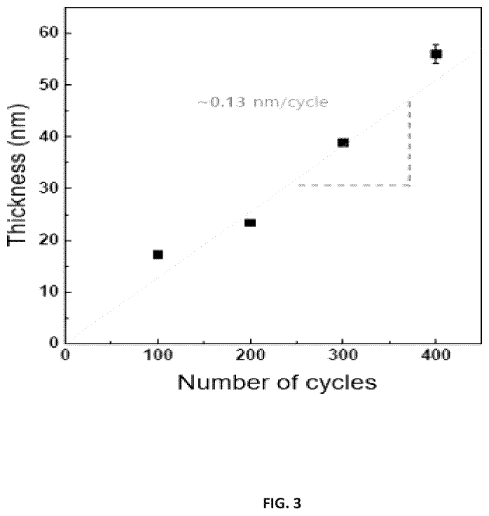

The growth characteristics of ALD YCₓ was investigated at 250° C. for 300 cycles. The thickness of YCₓ films saturates beyond 10 s of precursor exposure, indicating a self-limiting surface reaction between the precursors and co-reactants. This suggests that no thermal self-decomposition of the precursor had occurred at this temperature, and the saturation was achieved through a self-limiting surface reaction between the adsorbed precursors and reactants. Similarly, with 10 s of H₂ plasma exposure, thickness saturation occurs. Therefore, the optimal pulsing condition was set as follows: precursor pulse of 10 s, precursor purge of 10 s, reactant pulse of 10 s with a RF power of 200 W, followed by a reactant purge of 10 s. The film thickness of the films deposited under the basic pulsing conditions showed a linear dependency on the number of reaction cycles, and the growth rate was 0.13 nm/cycle, as shown in FIG. 3.

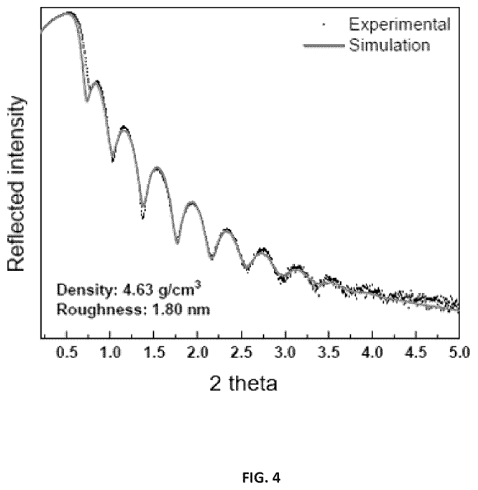

The density and roughness of the YCₓ films deposited under the optimal pulsing conditions were analyzed by the XRR (X-ray reflectivity). The density of YCₓ film was 4.63 g/cm³, which is almost same as the bulk value for Y₂C (4.626 g/cm³) and the roughness of the ALD-YCₓ film was 1.8 nm, as shown in FIG. 4.

To investigate the chemical composition of the YCₓ films, STEM-EDS (Scanning Transmission Electron Microscopy—Energy Dispersive X-ray Spectroscopy) analysis was conducted. The EDS analysis showed that the composition was Y₂C (C/Y=0.47). Also, The TEM used to examine the microstructure of the YCₓ films on trench structure by analyzing corresponding selected-area diffraction pattern (SADP) of ALD YCₓ. The SADP of ALD YCₓ shows a ring pattern with bright dots, indicating a poly crystalline structure of ALD YCₓ. We calculated the d-spacing of ring patterns of ALD YCₓ, which corresponds to rombohedral Y₂C crystal structure and GIAXRD (Grazing Incidence X-Ray Diffraction) patterns.

YCₓ was deposited with a cap layer of “X” on the trench structure (bottom width of 275 nm and aspect ratio (AR) of ~1.45) with an ALD-YCₓ layer. XTEM images at the top and bottom of the trench revealed ALD-YCₓ thicknesses of 15.4 and 14.7 nm, respectively, suggesting ~95% step coverage. The excellent step coverage on this nanoscale trench showed that the YCₓ film was deposited under ideal ALD growth conditions without partial decomposition of the precursor.

It will be understood that many additional changes in the details, materials, steps, and arrangement of parts, which have been herein described and illustrated in order to explain the nature of the invention, may be made by those skilled in the art within the principle and scope of the invention as expressed in the appended claims. Thus, the present invention is not intended to be limited to the specific embodiments in the examples given above and/or the attached drawings.

While embodiments of this invention have been shown and described, modifications thereof may be made by one skilled in the art without departing from the spirit or teaching of this invention. The embodiments described herein are exemplary only and not limiting. Many variations and modifications of the composition and method are possible and within the scope of the invention. Accordingly, the scope of protection is not limited to the embodiments described herein, but is only limited by the claims which follow, the scope of which shall include all equivalents of the subject matter of the claims.

1. A method for forming rare earth carbide films, the method comprising the steps of:
a) exposing a substrate to a vapor of a rare earth-containing film-forming composition;
b) exposing the substrate to a co-reactant;
c) depositing at least part of the cyclopentadienyl rare earth-containing precursor onto the substrate to form the rare earth carbide film; and
d) repeating the steps of a) and c) until a desired thickness of the rare earth carbide films is deposited on the substrate using a vapor deposition process,
wherein the rare earth-containing film-forming composition comprises a cyclopentadienyl rare earth-containing precursor having the formula: 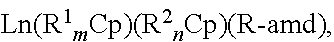
wherein R-amd is an amidinate ligand, RNC(CH₃)═NR, wherein the two R groups are the same or different; Cp is cyclopentadienyl; Ln is selected from Sc, Y, La, Ce, Pr, Nd, Pm, Sm, Eu, Gd, Tb, Dy, Ho, Er, Tm, Yb or Lu; R¹, R², and R each are independently selected from a hydrogen atom, a C₁ to C₅ linear or branched alkyl-group, a C₃ to C₅ cyclic alkyl-group; and m and n are integers.

2. The method of claim 1, wherein R is selected from Me, Et, nPr, iPr, nBu, iBi, sBu or tBu.

3. The method of claim 1, wherein Ln is Sc, Y, La, Ce, Pr, Nd, Pm, Sm, Eu, Gd, Tb, Dy, Ho, Er, Tm, Yb or Lu.

4. The method of claim 1, wherein Ln is Y.

5. The method of claim 1, wherein the cyclopentadienyl rare earth-containing precursor is Y(EtCp)₂(iPr-amd).

6. The method of claim 1, wherein the co-reactant is H₂ or plasma H₂.

7. The method of claim 1, wherein the vapor deposition process is a plasma enhanced ALD process.

8. The method of claim 1, wherein a ratio of rare earth to carbon in the rare earth carbide film is between 0.3 and 4.

9. The method of claim 1, wherein a ratio of rare earth to carbon in the rare earth carbide film is between 0.5 and 2.

10. The method of claim 1, wherein the substrate is SiO.

11. The method of claim 1, wherein a deposition temperature is held between about 100° C. and about 800° C.

12. The method of claim 1, wherein a deposition temperature is held between about 150° C. and about 500° C.

13. A method for forming rare earth carbide films, the method comprising the steps of:
a) exposing a substrate to a vapor of Y(EtCp)₂(iPr-amd);
b) exposing the substrate to a co-reactant;
c) depositing at least part of Y(EtCp)₂(iPr-amd) onto the substrate to form the rare earth carbide film; and
d) repeating the steps of a) and c) until a desired thickness of the rare earth carbide films is deposited on the substrate using a vapor deposition process.

14. The method of claim 13, wherein the co-reactant is H₂ or plasma H₂.

15. The method of claim 13, wherein a range of deposition temperature is from approximately 150 to approximately 350° C.

16. The method of claim 13, wherein the vapor deposition process is an atomic layer deposition (ALD) process.

17. The method of claim 13, wherein the vapor deposition process is a plasma enhanced ALD process.

18. A method for forming YCₓ films, wherein x is between 0.3 and 4, the method comprising the steps of:
a) exposing a SiO substrate to a vapor of Y(EtCp)₂(iPr-amd);
b) exposing the SiO substrate to a co-reactant H₂ plasma;
c) depositing at least part of Y(EtCp)₂(iPr-amd) onto the substrate to form the YCₓ film; and
d) repeating the steps of a) and c) until a desired thickness of the YCₓ films is deposited on the SiO substrate using ALD process.

19. The method of claim 18, wherein x is between 0.5 and 2.

20. The method of claim 18, wherein a range of deposition temperature is from approximately 150° C. to approximately 350° C.
